(19) United States
(12) Patent Application Publication
(10) Pub. No.: US 2015/0235817 A1
(43) Pub. Date: Aug. 20, 2015

(54) MAGNETRON SPUTTERING APPARATUS AND MAGNETRON SPUTTERING METHOD

(71) Applicant: Tohoku University, Sendai-shi, Miyagi (JP)

(72) Inventor: Tetsuya Goto, Sendai-shi (JP)

(21) Appl. No.: 14/376,519

(22) PCT Filed: Oct. 26, 2012
(86) PCT No.: PCT/JP2012/006899

§ 371 Date: Aug. 4, 2014

(51) Int. Cl. H01J 37/34

(52) U.S. Cl. CPC H01J 37/3405

(57) ABSTRACT

A magnetron sputtering apparatus including a first magnet array arranged helically, a second magnet array arranged side by side with the first magnet array, a stationary magnet disposed in the circumference of the first and second magnet arrays, a magnet rotation mechanism causing the first and second magnet arrays to rotate around a rotation axis, and a plurality of magnetic induction members which is disposed between the outer perimeter of the first and second magnet arrays and the stationary magnet in a direction crossing the rotation axis direction and arranged in the rotation axis direction when viewed from the side of a target, and attracts magnetic force lines coming out from the first magnet array to guide the magnetic force lines to the side of the target or attracts magnetic force lines coming in from the side of the target to guide the magnetic force lines to the second magnet array.

### TECHNICAL FIELD

The present invention relates to a magnetron sputtering apparatus and a magnetron sputtering method.

### BACKGROUND ART

In the manufacturing of a liquid crystal display element, a semiconductor element, and the like, there is required a process of forming a thin film made of metal or insulating material on a substrate. A film deposition method using a sputtering apparatus is used for this thin film formation process. The sputtering apparatus excites inert gas such as argon gas into plasma with a high DC voltage or a high frequency power, activates, melts, and disperses a target of a source material for thin film formation with this plasma gas, and deposits this material onto a substrate. For the sputtering apparatus, there is proposed a magnetron sputtering apparatus using a magnet rotation mechanism, which can reduce manufacturing cost by increasing a film deposition speed and improving a target utilization efficiency, and allow stable and long-term operation (refer to patent literature 1). This apparatus includes a magnet array including a plurality of magnets arranged helically on an outer perimeter of a rotation axis so that magnetic poles having the same polarity face outward, and a stationary magnet arranged in the circumference of the magnet array facing the target. By means of rotating the magnet array around the rotation axis, a magnetic field loop of a horizontal magnetic field which is formed in the vicinity of a target surface and is horizontal to the target surface is moved in the rotation axis direction to increase the film deposition speed and also to improve the target utilization efficiency.

### CITATION LIST

### Patent Literature

PTL 1: International Publication No. 2007/043476A1

### SUMMARY OF INVENTION

### Technical Problem

Generally, for performing film deposition onto a larger area substrate with a high throughput in the magnetron sputtering, it is effective to increase a target area and also increase an erosion region. For increasing the erosion region in a magnetron sputtering apparatus using a magnet rotation mechanism as described above, it is possible to increase the erosion region by increasing the whole length of the magnet rotation mechanism in the longitudinal direction (rotation axis direction). For increasing the erosion region in a width direction crossing the longitudinal direction of the magnet rotation mechanism, however, when the distance between the magnet array and the stationary magnet is increased, the magnetic field strength in the region between the magnet array and the stationary magnet on the target surface is reduced and it becomes difficult to confine plasma onto the target surface stably. When, for preventing this problem, the diameter of the spiral forming the magnet array is increased or the plural magnet rotation mechanisms are arranged side by side, the amount of the magnet to be used becomes huge and apparatus cost is considerably increased. Further, when the amount of the magnet to be used becomes huge, the force applied between the magnets also becomes large and it becomes difficult to secure stable operation of the apparatus.

One object of the present invention is to provide a magnetron sputtering apparatus using the magnet rotation mechanism and a magnetron sputtering method using this apparatus, in which the erosion region can be increased particularly in the width direction of the target as the target area is increased, while suppressing the use amount of the magnet to a minimum.

### Solution to Problem

A magnetron sputtering apparatus of the present invention includes:

a target disposed so as to face a plasma formation space;

a first magnet array which is disposed on an side opposite to the plasma formation space with respect to the target, is arranged helically around a rotation axis along a surface of the target on a side of the plasma formation space, and includes a plurality of magnets with N-poles facing outward in a radial direction;

a second magnet array which is arranged helically around the rotation axis, is arranged side by side with the first magnet array, and includes a plurality of magnets with S-poles facing outward in the radial direction;

a stationary magnet which is disposed in a circumference of the first and second magnet arrays when viewed from a side of the target and formed by a magnet having an N-pole or an S-pole on a side facing the target, for forming a loop magnetic field pattern that moves on the surface of the target in a direction of the rotation axis in cooperation with the first and second magnet arrays that rotate;

a magnet rotation mechanism which supports the first and second magnet arrays and causes the first and second magnet arrays to rotate around the rotation axis; and

a plurality of magnetic induction members which is disposed at least partially between an outer perimeter of the first and second magnetic arrays and the stationary magnet in a direction crossing the rotation axis direction and arranged along the rotation axis direction when viewed from the target side, and attracts magnetic force lines coming out from the first magnet array to guide the magnetic force lines to the target side or attracts magnetic force lines coming in from the target side to guide the magnetic force lines to the second magnet array.

A magnetron sputtering method of the present invention deposits a film of material of the target on a substrate to be processed using the magnetron sputtering apparatus according to any of claims 1 to 3, while confining plasma formed in the plasma formation space to a vicinity of the surface of the target by rotating the first and second magnet arrays.

### Advantageous Effects of Invention

According to the present invention, by effectively utilizing the magnetic field of the magnet in a state relatively apart from the target among the plural magnets constituting the first and second magnet arrays that rotate as the magnetic field for confining the plasma, it is possible to expand the erosion region in the width direction of the target while suppressing the use amount of the magnets to a minimum as the target area is increased. As a result, improvement in a film deposition rate and throughput is realized.

### BRIEF DESCRIPTION OF DRAWINGS

FIG. 1 is a cross-sectional diagram showing an example of a magnetron sputtering apparatus;

FIG. 2 is a perspective view of a magnet rotation mechanism, magnet arrays, and a stationary magnet in FIG. 1;

FIG. 3 is a diagram for explaining an erosion region;

FIG. 4 is a cross-sectional diagram of a magnetron sputtering apparatus according to an embodiment of the present invention;

FIG. 5 is a diagram showing a magnet rotation mechanism, magnet arrays, a fixed magnet, and a magnetic induction member in the apparatus of FIG. 4, and a plan view viewed from the target side;

FIG. 6 is a diagram showing a shape of the magnetic induction member;

FIG. 7 is a diagram showing an arrangement of the magnetic induction member and a side view viewed in a direction horizontal to a target surface;

FIG. 8A is a schematic diagram for explaining a property of a magnetic material;

FIG. 8B is a schematic diagram for explaining a property of the magnetic material;

FIG. 8C is a schematic diagram for explaining a principle of the present invention;

FIG. 9 is a diagram for explaining an action of the magnetic induction member;

FIG. 10A is a diagram for explaining an action of the magnetic induction member and a cross-sectional diagram along the direction XA-XA of FIG. 9;

FIG. 10B is a diagram for explaining an action of the magnetic induction member and a cross-sectional diagram along the direction XB-XB of FIG. 9;

FIG. 10C is a diagram for explaining an action of the magnetic induction member and a cross-sectional diagram along the direction XC-XC of FIG. 9;

FIG. 11A is a diagram showing a distribution of magnetic force lines in a case without the magnetic induction member, corresponding to FIG. 10A;

FIG. 11B is a diagram showing a distribution of magnetic force lines in a case without the magnetic induction member, corresponding to FIG. 10B;

FIG. 12 is a graph showing a relationship between an opening width of the stationary magnet and intensity of a horizontal magnetic field loop pattern; and

FIG. 13 is a schematic diagram showing a magnetic induction member according to another embodiment of the present invention.

### DESCRIPTION OF EMBODIMENTS

Hereinafter, with reference to the drawings, embodiments of the present invention will be explained in detail. Note that, in the present specification and the drawings, a constituent element having substantially the same functional configuration is provided with the same sign and repeated explanation will be omitted.

[Basic Configuration of a Magnetron Sputtering Apparatus]

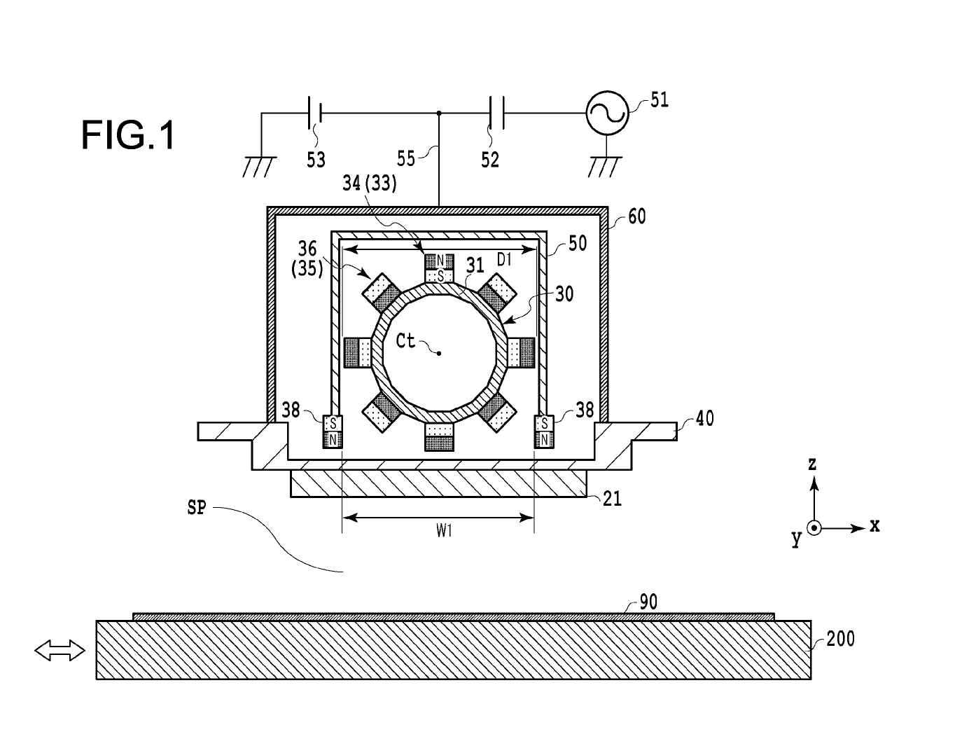

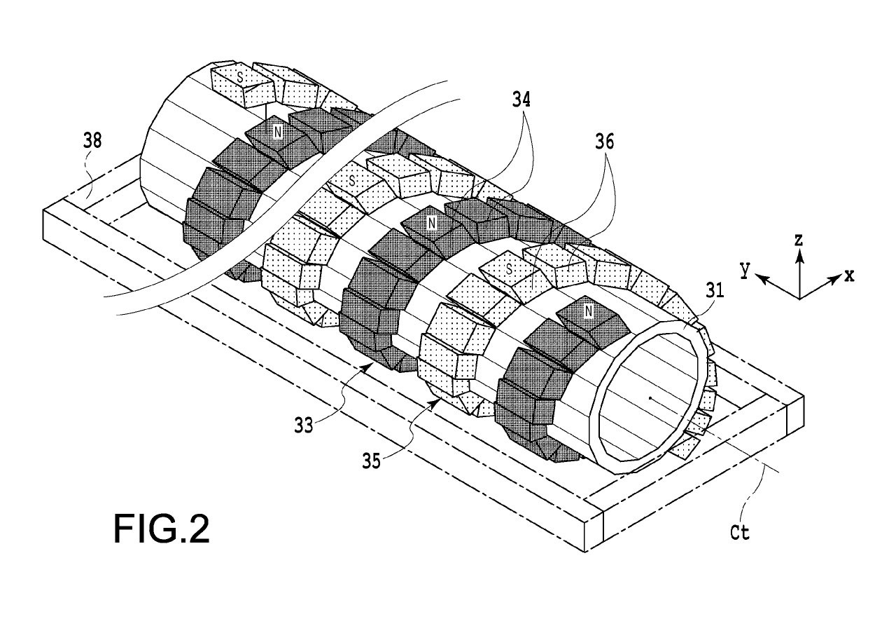

FIG. 1 is a diagram showing an example of a magnetron sputtering apparatus to which the present invention is to be applied, and FIG. 2 is a perspective view showing a magnet rotation mechanism, a magnet array, and a stationary magnet shown in FIG. 1. This apparatus includes a target 21 disposed so as to face a plasma formation space SP, a magnet rotation mechanism 30, plural magnets 34 constituting a first magnet array 33 to be described below, plural magnets 36 constituting a second magnet array 35 to be described below, and a stationary magnet 35 disposed in the circumference of the first and second magnet arrays 33 and 35. Here, in FIG. 1, reference numeral 40 denotes a backing plate to which the target 21 is bonded, reference numeral 50 denotes a magnetic material cover, reference numeral 51 denotes an RF power source for plasma excitation, reference numeral 52 denotes a blocking capacitor, reference numeral 53 denotes a DC power source for plasma excitation and target DC voltage control, reference numeral 60 denotes an aluminum cover, reference numeral 55 denotes a feeder line for supplying power to the target 21 via the aluminum cover 60 and the backing plate 40, reference numeral 90 denotes a substrate to be processed, and reference numeral 200 denotes a movable stage mounting and moving this substrate to be processed 90.

The magnet rotation mechanism 30 has a hollow rotation axis 31, supports the first and second magnet arrays 33 and 35 on an outer periphery of the rotation axis 31, and rotates the first and second magnet arrays 33 and 35 around the rotation axis Ct. The rotation axis 31 has a cross-sectional outer shape of a regular hexadecagon, and the plural magnets 34 and 36 are attached to the respective planes thereof. Both ends of the rotation axis 31 are supported rotatably by a mechanism which is not shown in the drawing, and also one end is connected to a gear unit and a motor which are not shown in the drawing to be rotated. For a material of the rotation axis 31, while typical stainless steel or the like may be used, a part or whole thereof is configured preferably with a ferromagnetic material having a small magneto-resistance such as an Fe-series high magnetic permeability alloy and iron, for example. In the present embodiment, the formation material of the rotation axis 31 is iron.

The first magnet array 33, as shown in FIG. 2, is disposed on a side opposite to the plasma formation space SP with respect to the target 21 and arranged helically around the rotation axis Ct along the surface of a target 21 on the side of the plasma formation space SP, and also configured with the plural magnets 34 with the N-poles facing outward in the radial direction. The second magnet array 35 is arranged helically around the rotation axis Ct, and also arranged side by side with the first magnet array 33 and includes the plural magnets 36 with the S-poles facing outward in the radial direction. Each of the magnets 34 and 36 includes plate-like magnets, and preferably a magnet having a high residual magnetic flux density, coercive force, and energy integral is used for generating a strong magnetic field stably. For example, an Sm—Co series sintered magnet having a residual magnetic flux density of approximately 1.1 T or further an Nd—Fe—B series sintered magnet having a residual magnetic flux density of approximately 1.3 T is preferably used. In the present embodiment, the Nd—Fe—B series sintered magnet is used. Each of the magnets 34 and 36 is magnetized in the direction perpendicular to the surface thereof.

The stationary magnet 35 is disposed so as to surround the circumference of the first and second magnet arrays 33 and 35 when viewed from the side of the target 21, and formed with a magnet having the S-pole on a side facing the target 21. Note that the stationary magnet may have the N-pole on the side facing the target 21. Here, for the stationary magnet 35, while a part provided in the direction of the rotation axis C and a part provided in the direction perpendicular thereto are connected, these parts maybe separated. Also as the stationary magnet 35, the same as the magnets 34 and 36, the Nd—Fe—B series sintered magnet is used.

The backing plate 40 disposed on an outer wall of a processing chamber which is not shown in the drawing via an insulator which is not shown in the drawing. The power frequency of the RF power source 51 is 13.56 MHz, for example. While the present embodiment employs an RF-DC coupled discharge method in which also a DC power can be superimposed, a DC discharge sputtering method using only a DC power source may be employed or an RF discharge sputtering method using only an RF power source may be employed.

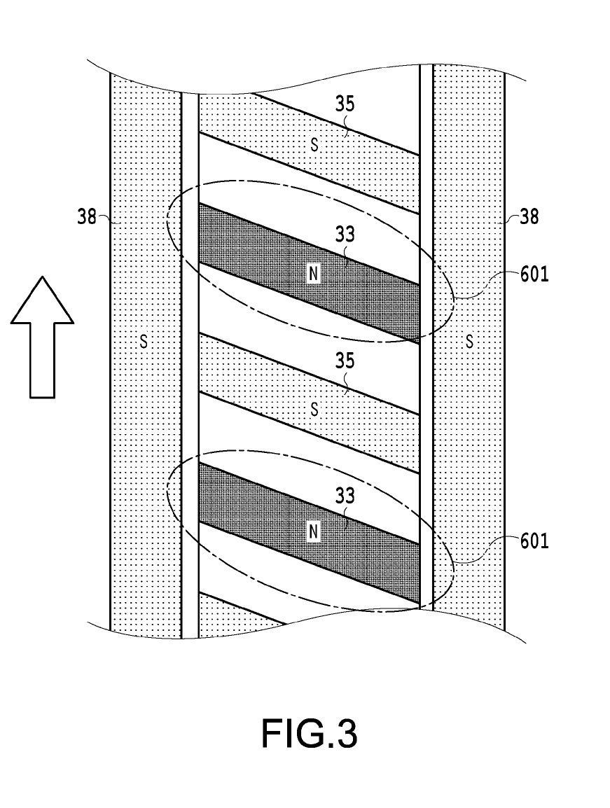

Next, by the use of FIG. 3, there will be explained formation of a loop magnetic field pattern which moves on the target surface in the magnetron sputtering apparatus. Here, a magnetic field forming this magnetic field pattern acts so as to confine plasma to the vicinity of the target surface and forms an erosion region where sputtering is performed on the target surface.

As shown in FIG. 3, when the first and second magnet arrays 33 and 35 provided on the rotation axis 31 are viewed from the side of the target 21, the circumference of the N-poles in the first magnet array 33 is approximately surrounded by the second magnet array 35 and the stationary magnet 38. Among magnetic force lines from the first magnet array 33, the magnetic force lines from the magnets 34 located relatively close to the target 21 pass the target 21 and then terminate at the S-poles of the second magnet array 35 or the stationary magnet 38 surrounding the magnets 34. Therefore, plural closed loop magnetic field patterns 601 are formed on the surface of the target 21. The magnetic field pattern 601 is a trajectory of a region where a magnetic field component in a direction perpendicular to the surface of the target 21 is zero and also only a magnetic field component horizontal to the surface of the target 21 exists, the plasma is confined in this closed loop magnetic field pattern (hereinafter, called a horizontal magnetic field loop) 601 and the magnetic field pattern 601 matches the erosion region. The plural magnetic field patters 601 move on the surface of the target 21 in a direction shown by the array along the rotation of the rotation axis 31. Note that, in the end parts of the first and second magnet arrays 33 and 35, the erosion region is generated sequentially from one end part, and this erosion region moves toward the other end part and vanishes sequentially at the other end part.

The surface of the target 21 is cut (eroded) efficiently across the whole surface by a time-average effect, and therefore the use efficiency of the target 21 is improved. An atom of the target 21 sputtered and flying out from the erosion region reaches and attaches to the substrate to be processed 90 disposed on the movable stage 200. Thereby, a thin film is formed on the substrate to be processed 90. Here, it is also possible to perform the film deposition while moving the substrate to be processed 90 against the target 21 by driving the movable stage 200 on which the substrate to be processed 90 is disposed, during the time when the plasma is excited on the surface of the target 21.

### First Embodiment

In the magnetron sputtering apparatus shown in FIG. 1, an opening width shown by W1 of the stationary magnet 38 in the width direction (direction perpendicular to the rotation axis Ct when viewed from the target side) is configured to be approximately the same as a magnet array diameter shown by D1 which is each diameter of the magnet arrays 33 and 35. This is because, when the opening width W1 is increased for increasing the size of the target 21 in the width direction, as will be described below, the magnetic field strength of the horizontal magnetic field loop 601 on the surface of the target 21 is reduced in a region relatively apart from the first and second magnet arrays 33 and 35 and the stationary magnet 38, and it becomes difficult to confine the plasma onto the target surface stably. Therefore, the present embodiment will explain a magnetron sputtering apparatus capable of coping with the increase in the size of the target 21 in the width direction without increasing the use amount of the magnets.

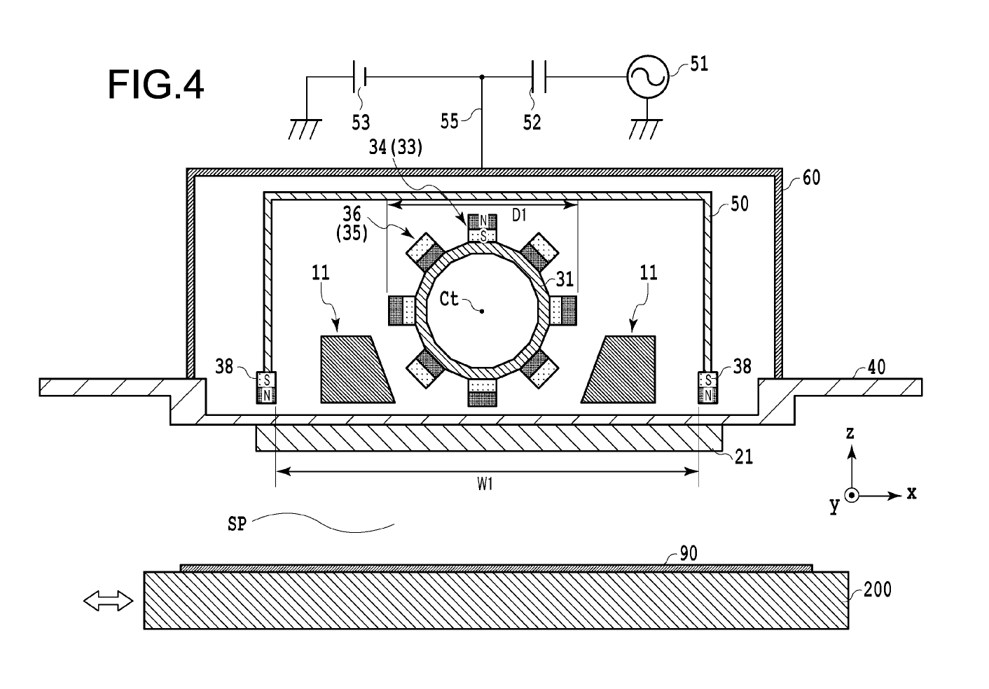

FIG. 4 is a cross-sectional view showing the magnetron sputtering apparatus according to a first embodiment of the present invention. Note that, in FIG. 4, the same reference numeral is used for a constituent element similar to one in the apparatus of FIG. 1. This apparatus is configured such that the opening width W1 of the stationary magnet 38 becomes sufficiently larger than the magnet array diameter D1, and also a magnetic induction member 11 is provided between the rotation axis 31 and the stationary magnet 38. This magnetic induction member 11 is provided for increasing the magnetic field strength of the moving horizontal magnetic field loop which is formed in the vicinity of the surface of the target 21, and particularly the magnetic field strength in a region between the first and second magnet arrays 33 and 35 and the stationary magnet 38, as will be described below.

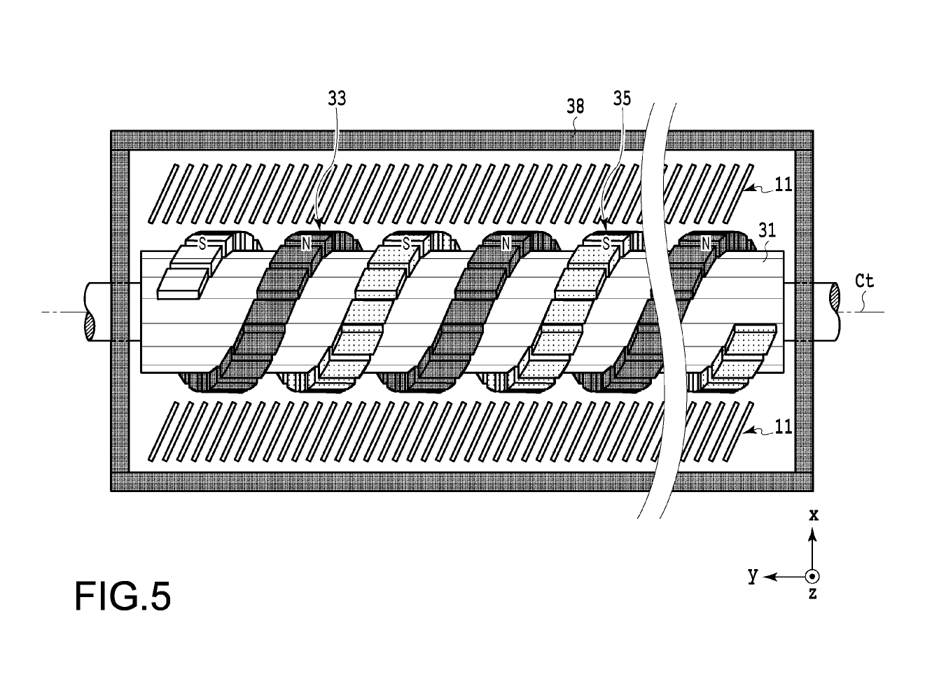

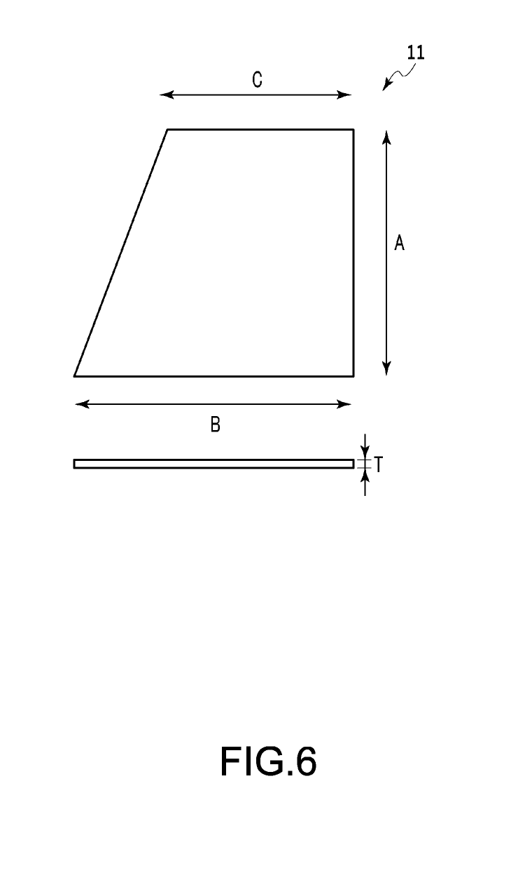

As shown in FIG. 5 and FIG. 6, the magnetic induction member 11 is formed by thin plate members, and the formation material of the magnetic induction member 11 is formed of magnetic material in which magnetic poles are generated by magnetic induction, and preferably formed of a ferromagnetic material having a small magneto-resistance such as a Ni—Fe series high magnetic permeability alloy and iron, for example. In the present embodiment, the magnetic induction member 11 is formed of the iron. The magnetic induction member 11 has a trapezoidal shape having two rectangular corners on one side as shown in FIG. 6, and the sizes shown in FIGS. 6 A, B, and C are 37 mm, 34 mm, and 22 mm, for example, respectively. Further, the thickness T is 2 mm, for example. As shown in FIG. 5, the plural magnetic induction members 11 are arranged along the rotation axis Ct on both sides of the rotation axis Ct between the first and second magnet arrays 33 and 35 and the stationary magnet 38, when viewed from the side of the target 21.

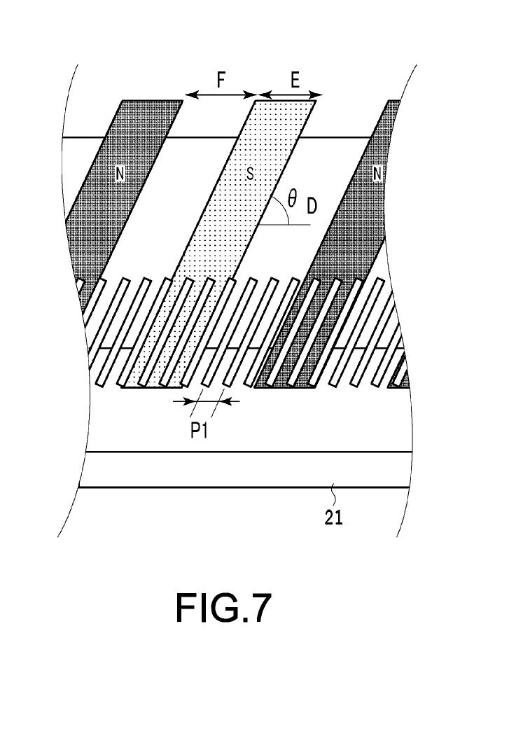

Next, with reference to FIG. 7, there will be explained a specific arrangement example of the magnetic induction member 11. FIG. 7 is a side view of the first and second magnet arrays and the magnetic induction member 11 when viewed along a direction horizontal to the surface of the target 21. The magnetic induction members 11 arranged inclined from the rotation axis Ct so as to have the same inclination angle as that of the first and second magnet arrays 33 and 35 (inclination angle of the spirals) which is shown by θD in FIG. 7. In the present embodiment, the inclination angle of the spiral is 65 degrees, and the magnetic induction member 11 is also inclined at 65 degrees to the rotation axis Ct. For preventing interference between the neighboring first and second magnet arrays 33 and 35, the magnetic induction member 11 is disposed at an angle matching the inclination angle of the spiral. Note that, when the inclination angle of the spiral is comparatively small, it is also possible to dispose the magnetic induction member 11 so as to cross the rotation axis Ct perpendicularly without being inclined to the rotation angle line Ct.

The plural magnetic induction members 11 are arranged at a predetermined arrangement pitch P1, and the pitch P1 is approximately 4 mm, for example. Further, as apparent from FIG. 7, the thickness of the magnetic induction member 11 in the direction of the rotation axis Ct is configured to become smaller than each width E of the magnets constituting the first and second magnet arrays 33 and 35 in the direction of the rotation axis Ct, and the arrangement pitch P1 of the magnetic induction members 11 in the direction of the rotation axis Ct is configured to become smaller than the spacing F between the first and second magnet arrays. The width E and the spacing F are 19 mm and 25 mm, for example, respectively. Under such a size condition, the two to three magnetic induction members 11 are disposed in the range of each width in the first and second magnet arrays. Note that the reason why the thickness and the arrangement pitch P1 of the magnetic induction member 11 is configured as above will be described below.

The position of the lower end part (end part facing the target 21) of the magnetic induction member 11 is set to have approximately the same height as that of the magnet located closest to the target 21 among the magnets in the first and second magnet arrays 33 and 35, in the direction perpendicular to the surface of the target 21.

While a support member supporting the magnet guidance member 11 is omitted from illustration, it is also possible to insert a plate-like member formed of non-magnetic material such as aluminum and resin, for example, between the plural magnetic induction members 11 for fixing the magnetic induction member 11 to the support member. At this time, the plural magnetic induction members 11 and the plural plate-like members are preferably formed as a unit. When the plate-like member is formed of nonmagnetic metal material such as aluminum, the plate-like member may be swaged with a bolt and nut or a rivet made of aluminum or may be fixed with a band-like frame in strong adhesion. When the plate-like member is made of resin, the plate-like members may be formed in a unit by means of dipping the plural magnetic induction members 11 which have been arranged tentatively having an equal spacing into melted resin and curing the resin. The plural magnetic induction members 11, while being preferably formed having the same material, the same shape, and the same size, are not always formed having the same material, the same shape, and the same size from the viewpoint of uniformity and work preciseness of the material. Further, this also depends on other factors, and, for example, sometimes depends on uniformity in shape or structure of the target 21 or the magnet rotation mechanism 30. Inconsideration of the above, the material, shape, and the size of this magnetic induction member 11 are preferably set in a range where the plasma formed between the target 21 and the magnet rotation mechanism 30 is caused to become uniform or substantially uniform without depending on a location. The arrangement spacing of the magnetic induction members 11 is preferably an equal spacing, a substantially equal spacing, or effectively equal spacing. However, if the uniformity of the plasma formed between the target 21 and the magnet rotation mechanism 30 is degraded depending on the non-uniformity of the target 21 and the magnet rotation mechanism 30 when the magnetic induction members 11 are arranged at an equal spacing, a substantially equal spacing, or an effectively equal spacing, the arrangement spacing of the magnetic induction members 11 may be changed intentionally so as to keep the uniformity of the plasma. For example, when the plural magnetic induction members 11 are arranged having the arrangement spacing which is gradually increased toward the center of the magnet rotation mechanism 30 along the rotation axis Ct of the magnet rotation mechanism 30, the above problem is comparatively easily solved and this configuration is preferable. While, in the explanation of the example in the embodiment of the present invention, it is explained to be a preferable example to dispose the first and second magnet arrays 33 and 35 helically along the circumference of the rotation axis Ct having an equal spacing, other than this example, depending on an example in the embodiment, the first and second magnet arrays 33 and 35 may be arranged helically having an unequal spacing, and, for the unequal spacing, the first and second magnet arrays 33 and 35 may be arranged helically having a pitch distance which is continuously increased toward the center of the magnet rotation mechanism 30 along the rotation axis Ct of the magnet rotation mechanism 30. While the width E of the first and second magnet arrays is explained or illustrated to have an equal size for explanation convenience. It is also a preferable example to change the width E according to a difference of a magnetic force level in the magnets constituting the magnet array or so as to cause the desired plasma to be formed as intended. For example, it is a preferable example to increase the width of the N-type magnet array larger than the width of the S-type magnet array according to a difference in the magnetic force levels of the magnets constituting the magnet arrays.

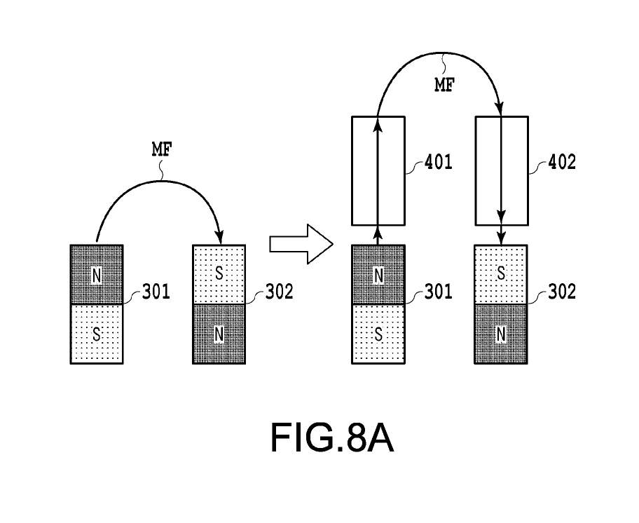

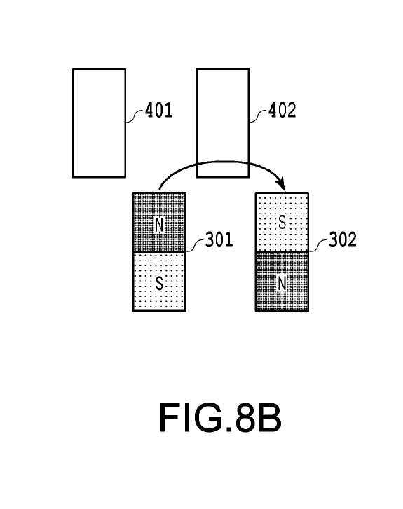

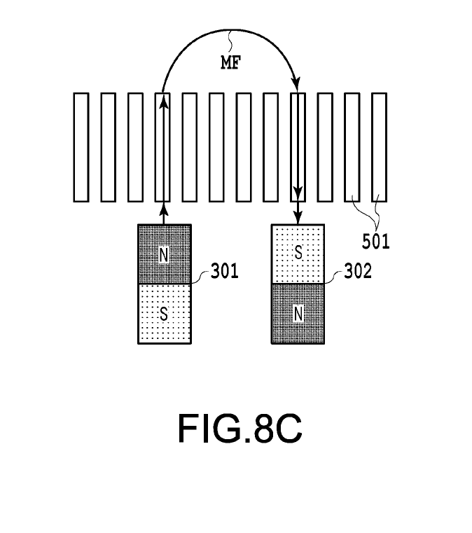

Next, with reference to FIG. 8A to FIG. 11B, action and effect of the magnetic induction member 11 will be explained. As shown in FIG. 8A, when two magnets 301 and 302 are disposed side by side having magnetic pole directions opposite to each other, a magnetic force line MF coming out from one magnet 301 is attracted by the other magnet 302 and goes into the magnet 302. When magnetic materials 401 and 402 which have approximately the same end surface widths as the magnets 301 and 302 are disposed at respective positions facing the magnets 301 and 302, since a magnetic force line tends to go through a magnetic material as far as possible by magnetic induction, a route of the magnetic force line MF can be extended to a position more apart from the magnets 301 and 302 as shown in FIG. 8A. As shown in FIG. 8B, however, when the magnets 301 and 302 move to positions not facing the magnetic materials 401 and 402, magnetism is shunted between the magnets and the magnetic force line MF and does not extend to a position apart from the magnets 301 and 302. Accordingly, as shown in FIG. 8C, plural magnetic materials 501 which have end surface widths smaller than the end surface widths of the magnets 301 and 302, are arranged having a spacing smaller than the end surface widths of the magnets 301 and 302. By the magnetic materials 501, the route of the magnetic force line MF can be extended to a position more apart from the magnets 301 and 302, and also the extended route of the magnetic force line MF can be maintained even when the magnets 301 and 302 move against the magnetic materials 501. This is because the magnetic plates are isolated from each other and magnetism is not shunted between the magnets.

For confining the plasma efficiently in the horizontal magnetic field loop region, it is necessary to set a minimum horizontal magnetic field strength in the horizontal magnetic field loop region to be at least not smaller than 100 gauss, preferably not smaller than 200 gauss, and more preferably not smaller than 300 gauss. As described above, when the opening width W1 of the stationary magnet 38 is formed to be sufficiently larger than the magnet array diameter D1, the minimum horizontal magnetic field strength is reduced in the horizontal magnetic field loop region. In the present embodiment, By the use of the principle shown in FIG. 8C, the magnetic induction member 11 acts so as to extend the route of the magnetic force line formed between the first magnet array 33, the second magnet array 35, and the stationary magnet 38 to enhance the magnetic field strength in the horizontal magnetic field loop.

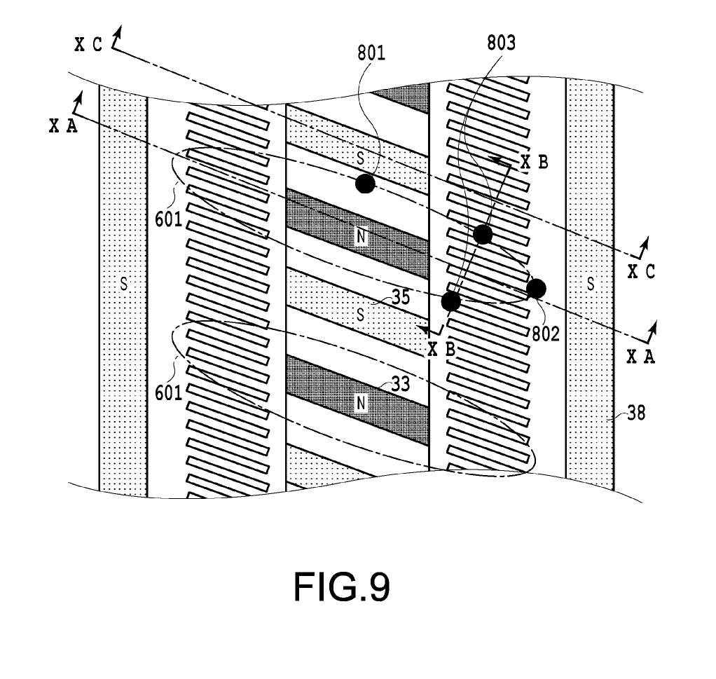

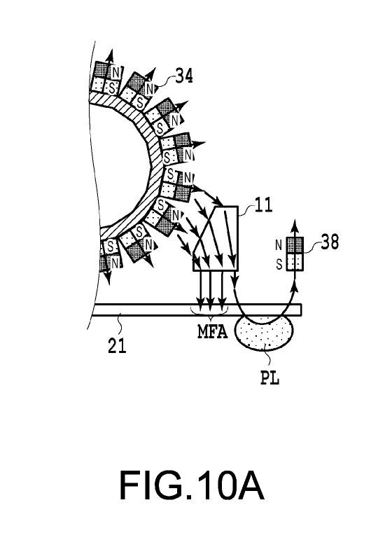

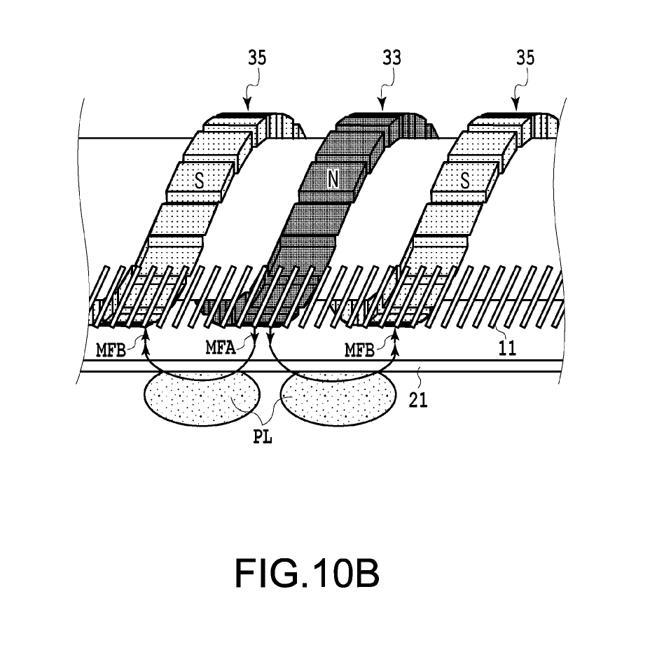

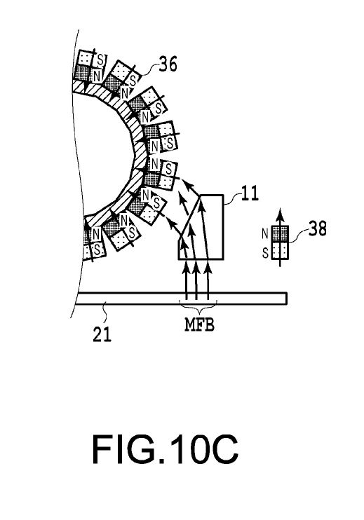

FIG. 9 is a diagram showing the first and second magnet arrays, the magnetic induction member, and the fixed target when viewed from the target. In FIG. 9, trajectory 601 shown by the chain line is a horizontal magnetic field loop formed on the surface of the target 21. FIG. 10A is an XA-XA cross-sectional view along the first magnet array 33 of FIG. 9, FIG. 10B is an XB-XB cross-sectional view perpendicular to the XA-XA line of FIG. 9, and FIG. 10C is an XC-XC cross-sectional view along the second magnet array 35 of FIG. 9. Here, each of FIG. 10A and FIG. 10C shows only a half of the magnet array on one side from the rotation axis Ct.

As shown in FIG. 10A, the magnetic force lines coming from the magnets 34 of the first magnet array 33 which is located not directly close to the surface of the target 21 but comparatively apart from the surface of the target 21 are attracted to one end part of the magnetic induction member 11 disposed between the first magnet array 33 and the stationary magnet 38 because of the above described property of magnetic material, and goes into the magnetic induction member 11. Since magnetic force lines have a property of gathering together to a material having a magnetic permeability as high as possible and also repelling one another, the magnetic force lines coming into the magnetic induction member 11 are guided to the target side through the inside of the magnetic induction member 11, and goes out from the lower end part of the magnetic induction member 11 toward the target 21. Among the magnetic force lies coming out from the magnetic induction member 11, the magnetic force lines located close to the stationary magnet 38 terminate at the stationary magnet 38. At this time, the horizontal magnetic field region (zero vertical magnetic field region) is formed on the surface of the target 21 as shown in FIG. 10A and confines the plasma PL there. This position corresponds to position 802 of FIG. 9.

The remaining magnetic force lines MFA coming out from the magnetic induction member 11 are guided to the side of the target 21 as shown in FIG. 10A and FIG. 10B. Then, the magnetic force lines MFA guided to the surface side of the target 21 terminate finally at the magnet 36 of the second magnet array 35 neighboring in the rotation axis direction as the magnetic force lines MFB. Also in this case, as shown in FIG. 10B and FIG. 10C, the magnetic force lines MFB coming from the side of the target 21 are attracted to the lower end part of the magnetic induction member 11 disposed between the second magnet array 35 and the stationary magnet 38, and guided to the magnet 36 of the second magnet array 35 through the inside of the magnetic induction member 11. At this time, the horizontal magnetic field region (zero vertical magnetic field region) is formed on the target surface and confines the plasma PL there, as shown in FIG. 10B. This location corresponds to position 803 of FIG. 9. In this manner, by utilizing the magnetic field of the magnet in a state relatively apart from the target 21 as the magnetic field for the plasma confinement using the magnetic induction member 11, it is possible to excite a wide horizontal magnetic field loop stably, even when the opening width W1 of the stationary magnet 38 is increased.

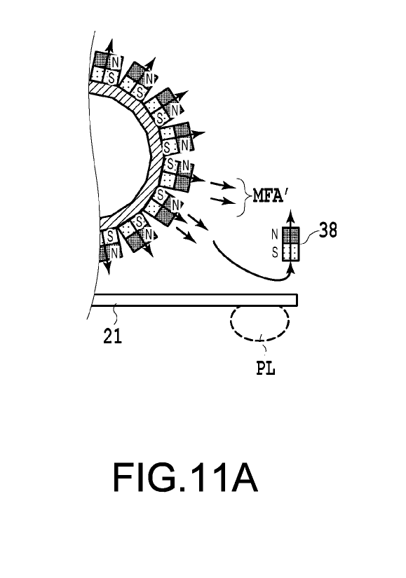

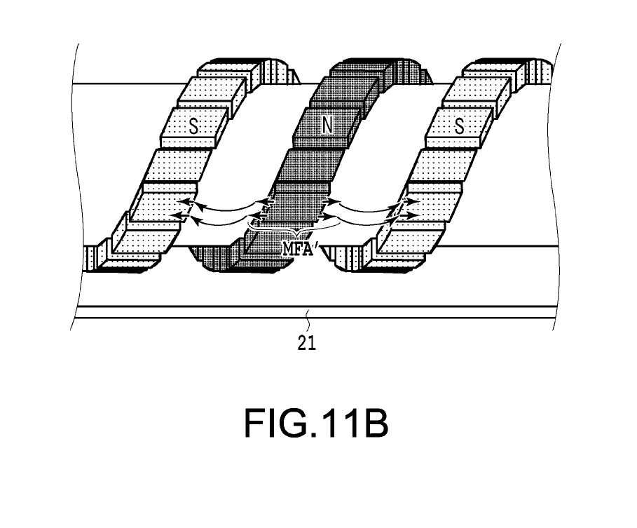

For comparison, there will be explained a case in which the opening width W1 of the stationary magnet 38 is increased without introduction of the magnetic induction member 11. In this case, the magnetic force lines coming out from the magnet located not directly close to the surface of the target 21 but comparatively apart from the surface of the target 21 are not directed toward the target 21 but dispersed in directions approximately perpendicular to the magnet surface as shown in FIG. 11A. While some of the magnetic force lines go toward the stationary magnet 38, since the magnetic induction member 11 does not exist, it is difficult to form the horizontal magnetic field loop as shown in FIG. 10A and to confine the plasma PL stably. Further, around position 803 of FIG. 10A, it is extremely difficult to form the horizontal magnetic field loop region having a large magnetic field strength on the surface of the target 21. This is because the magnetic force lines MFA′ coming out from the N-pole of the magnet located apart from the surface of the target 21 do not go to the side of the target 21 but go to the S-pole of the neighboring magnet without going through the surface of the target 21, as shown in FIG. 11B. Accordingly, when the magnetic induction member 11 does not exist, even if high density plasma is excited at position 801 shown in FIG. 9 where the magnet is located close to the target 21, the plasma is dispersed at positions 802 and 803 where the horizontal magnetic field is weak, and it becomes difficult to excite the plasma stably.

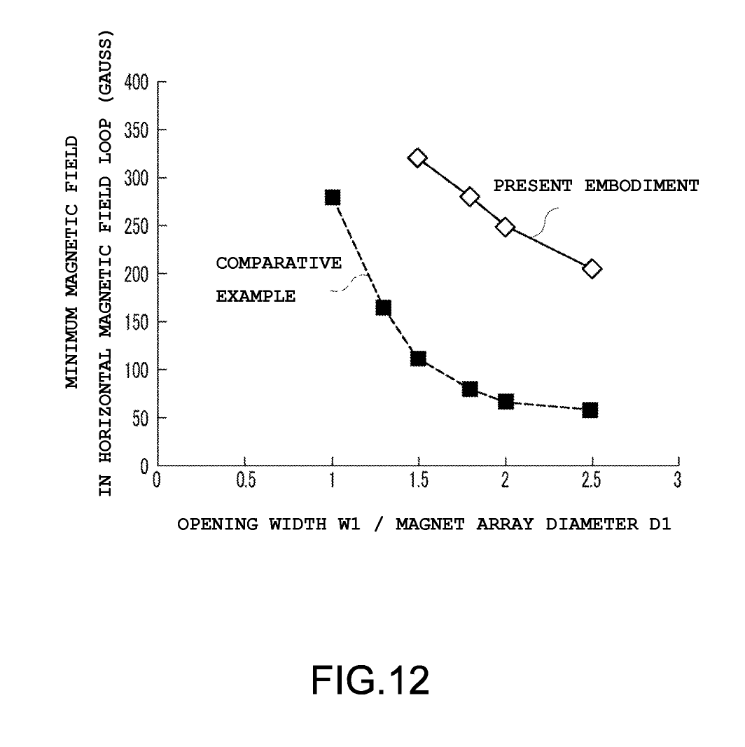

FIG. 12 is a graph plotting a minimum horizontal magnetic field strength in the horizontal magnetic field loop when the opening width W1 of the stationary magnet 38 is changed. Comparative example shows the minimum horizontal magnetic field strength in the horizontal magnetic field loop in an apparatus without the magnetic induction member 11. In the present embodiment, even when the opening width W1 of the stationary magnet 38 is increased up to twice the magnet array diameter D1, it is found that the minimum horizontal magnetic field exceeds 200 gauss. Here, the maximum horizontal magnetic field in the horizontal magnetic field loop is approximately 750 gauss near the center of the target in the width direction, and this value changes little even when the opening width W1 of the stationary magnet 38 is changed. By introducing the magnetic induction member 11, it is possible to increase the width of the target 21 up to twice the magnet array diameter D1 and to expand the horizontal magnetic loop fully across the target width. On the other side, in comparative example without the magnetic induction member 11, when the opening width W1 exceeds a size of approximately 1.5 times the magnet array diameter D1, the minimum horizontal magnetic field becomes lower than 100 gauss and the plasma cannot be excited stably.

### Second Embodiment

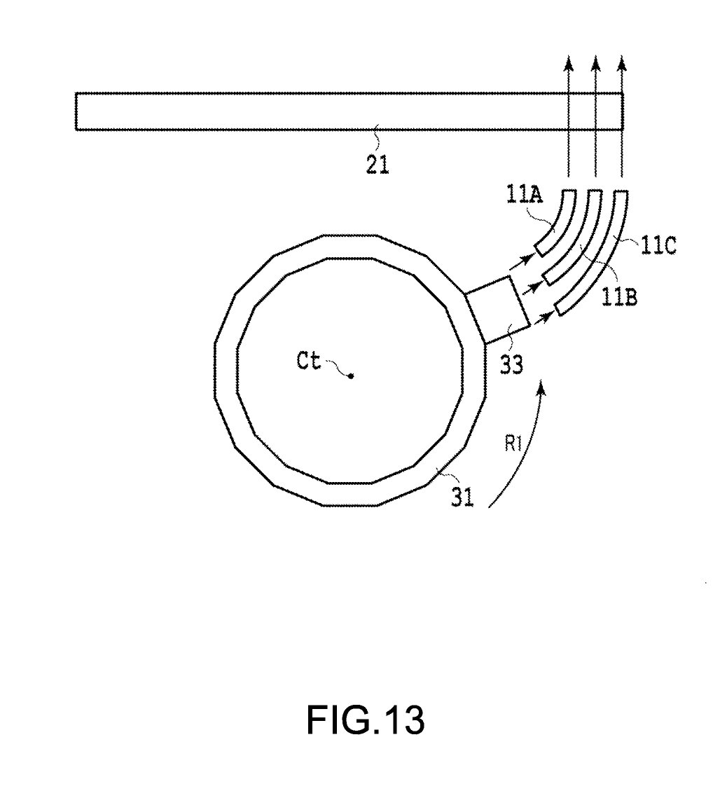

FIG. 13 is a diagram showing a structure of a magnetic induction member according to another embodiment of the present invention. The plural magnetic induction members shown in FIG. 13 are arranged in the direction of the rotation axis Ct as in the first embodiment, and also the plural magnetic induction members are arranged in the rotation direction R1 of the rotation axis 31 as indicated by reference symbols 11A to 11C. In addition, each of the magnetic induction members 11A to 11C are bent so that one end part faces the magnet of the first magnet array 33 which is apart from the surface of the target 21 and the other end part faces the target 21.

Since the magnetic induction member 11 formed with a plate of magnetic material in the first embodiment has an isotropic magneto-resistance inside the magnetic induction member 11, a large portion of the magnetic lines go toward the surface of the target 21, but some of the magnetic force lines are dispersed from the right end part of FIG. 10A and a component dispersed in the horizontal direction is generated.

On the other side, in the present embodiment, the magnetic induction members 11A to 11C are divided into plural parts in the rotation direction R1, and the shape thereof is a bent shape along a line starting from the first magnet array 33 toward the surface of the target 21, and thereby it becomes possible to reduce a ratio of the dispersed magnetic force lines and to guide the magnetic force lines efficiently to the target surface.

Here, preferably the width of the magnetic induction member is smaller than the width of the facing magnet and the arrangement pitch has a size so as to cause two or more magnetic induction members to be arranged in the magnet width and between the magnets, in either of the direction of the rotation axis C and the rotation direction R1.

While, in the above, the embodiments of the present invention have been explained in detail with reference to the attached drawings, the present invention is not limited to these examples. While, in the above embodiments, the spiral magnet arrays are configured to have two arrays, the present invention is not limited to this case, and, for example, more magnet arrays can be formed such as four arrays, six arrays, and eight arrays. while, in the above embodiments, the magnetic induction member is disposed between the outer perimeter of the magnet arrays and the stationary magnet when viewed from the target side, at least a part of the magnetic induction member may be disposed between the outer perimeter of the magnet arrays and the fixed magnet, and the magnetic induction member can be configured to overlap the magnet arrays when viewed from the target side. Obviously, a person having a usual knowledge in the technical field including the present invention can reach various kinds of variation example or modification example in the scope of the technical idea described in claims, and it is understood that these examples are obviously included in the technical range of the present invention.

### INDUSTRIAL APPLICABILITY

The magnetron sputtering apparatus according to the present invention can be not only used for forming an insulating film or a conductive film on a semiconductor wafer or the like, but also applied to formation of various covering films on a substrate such as a glass of a flat display device and used for sputtering film deposition in manufacturing of a storage device and other electronic devices.

1-4. (canceled)

5. A magnetron sputtering apparatus, comprising:
a first magnet array consisting of a plurality of magnets arranged helically around a rotation axis along a predetermined plane, respective N-poles of the plurality of magnets facing outward in a radial direction;
a second magnet array consisting of a plurality of magnets arranged helically around the rotation axis and side by side with the first magnet array, respective S-poles of the plurality of magnets facing outward in a radial direction;
a stationary magnet configured to form a loop magnetic field pattern in cooperation with the first and second magnet arrays, the stationary magnet consisting of a magnet having a N-pole or a S-pole on a side facing the predetermined plane and being disposed surrounding the first and second magnet arrays when viewed from the predetermined plane side, the loop magnetic field pattern moving on the predetermined plane in a direction along the rotation axis while the first and second magnet arrays are rotated;
a magnet rotation mechanism configured to support the first and second magnet arrays and cause the first and second magnet arrays to rotate about the rotation axis; and
a plurality of magnetic induction members configured to attract magnetic force lines from the first magnet array so as to lead the magnetic force lines to the predetermined plane side or attract magnetic force lines from the predetermined plane side so as to lead the magnetic force lines to the second magnet array, the plurality of magnetic induction members being arrayed in a direction along the rotation axis, each of the plurality of magnetic induction members extending in a direction crossing the rotation axis and disposed at least partially between the first and second magnetic arrays and the stationary magnet when viewed from the predetermined plane side.

6. The magnetron sputtering apparatus according to claim 5, wherein
a thickness of each of the plurality of magnetic induction members in the rotation axis direction is smaller than a width of the magnets constituting the first and second magnet arrays in the rotation axis direction, and an array pitch of the plurality of magnetic induction members in the rotation axis direction is smaller than a spacing between the first and second magnet arrays.

7. The magnetron sputtering apparatus according to claim 5, wherein
the plurality of magnetic induction members includes a plurality of members arranged in a rotation direction of the magnet rotation mechanism.

8. A magnetron sputtering method using a magnetron sputtering apparatus, the apparatus comprising:
a first magnet array consisting of a plurality of magnets disposed on a side opposite to a plasma formation space with respect to a target facing the plasma formation space and arranged helically around a rotation axis along a surface of the target on the plasma formation space side, respective N-poles of the plurality of magnets facing outward in a radial direction;
a second magnet array consisting of a plurality of magnets arranged helically around the rotation axis and side by side with the first magnet array, respective S-poles of the plurality of magnets facing outward in a radial direction;
a stationary magnet configured to form a loop magnetic field pattern in cooperation with the first and second magnet arrays, the stationary magnet consisting of a magnet having a N-pole or a S-pole on a side facing the target and being disposed surrounding the first and second magnet arrays when viewed from the target side, the loop magnetic field pattern moving on the surface of the target in a direction along the rotation axis while the first and second magnet arrays are rotated;
a magnet rotation mechanism configured to support the first and second magnet arrays and cause the first and second magnet arrays to rotate about the rotation axis; and
a plurality of magnetic induction members configured to attract magnetic force lines from the first magnet array so as to lead the magnetic force lines to the target side or attract magnetic force lines from the target side so as to lead the magnetic force lines to the second magnet array, the plurality of magnetic induction members being arrayed in a direction along the rotation axis, each of the plurality of magnetic induction members extending in a direction crossing the rotation axis and disposed at least partially between the first and second magnetic arrays and the stationary magnet when viewed from the target side,
the method comprising depositing a film of material of the target on a substrate to be processed while confining plasma formed in the plasma formation space to near the surface of the target by rotating the first and second magnet arrays.
